(19) United States
(12) Patent Application Publication
(10) Pub. No.: US 2021/0013813 A1
(43) Pub. Date: Jan. 14, 2021

(54) CONTROLLERS, CONTROL CIRCUITS AND METHODS FOR CONTROLLING INTELLLIGENT DEVICES

(71) Applicant: Beijing Big Moment Technology Co., Ltd, Beijing (CN)

(72) Inventors: Sterling DU, Shanghai (CN); Zhimou REN, Chengdu (CN)

(21) Appl. No.: 16/894,377

(22) Filed: Jun. 5, 2020

(30) Foreign Application Priority Data
Jul. 11, 2019 (CN) 201910501533.0

(51) Int. Cl. H02M 7/06; H03K 21/08

(52) U.S. Cl. CPC H02M 7/06; H03K 21/08

(57) ABSTRACT

A controller includes: an input terminal, coupled to a power switch, operable for generating a parameter signal indicating an on/off state of the power switch; a power terminal, coupled to a power source, operable for receiving electric power supplied by the power source to power the controller; an output terminal, coupled to a forwarding module, operable for outputting an indicating signal and a control signal, to enable the forwarding module to read the control signal based on the indicating signal, thus selecting an operating mode of an intelligent device, where both the control signal and the indicating signal are generated by the controller based on the parameter signal.

### RELATED APPLICATION

This application claims priority to Chinese Patent Application No. 201910501533.0, titled “Controllers, Control Circuits and Methods for Controlling Intelligent Devices,” filed on Jun. 11, 2019, with the National Intellectual Property Administration of the People's Republic of China (CNIPA).

### BACKGROUND

At present, intelligent devices are usually controlled by a mobile terminal (e.g., a smart phone) or a remote control. The mobile terminal or the remote control is considered to be simply an accessory. Sometimes, they do not have enough remaining battery capacity or cannot be found, and so they cannot be used to control the intelligent devices. In addition, some people do not have the training or desire to use the mobile terminal or the remote control.

### SUMMARY

Embodiments in accordance with the present invention provide controllers, control circuits, and methods for controlling intelligent devices.

In embodiments, a controller includes: an input terminal, coupled to a power switch, operable for generating a parameter signal indicating an on/off state of the power switch; a power terminal, coupled to a power source, operable for receiving electric power supplied by the power source to power the controller; an output terminal, coupled to a forwarding module, operable for outputting an indicating signal and a control signal, to enable the forwarding module to read the control signal based on the indicating signal, thus selecting an operating mode of an intelligent device, where both the control signal and the indicating signal are generated by the controller based on the parameter signal.

In embodiments, a control circuit includes: a controller, coupled to a power switch, operable for receiving electric power from a power source, and for generating a control signal and an indicating signal based on an on/off state of the power switch; a forwarding module, coupled to the controller, operable for receiving the indicating signal, for reading the control signal based on the indicating signal, and for transmitting the control signal to an intelligent device, to select an operating mode of the intelligent device.

In embodiments, a method for controlling an intelligent device with a control circuit includes: generating, using a controller, a parameter signal indicating an on/off state of the power switch; generating, using the controller, a control signal and an indicating signal based on the parameter signal; and receiving, using a forwarding module, the indicating signal, reading the control signal based on the indicating signal, and transmitting the control signal to the intelligent device, to select an operating mode of the intelligent device.

### BRIEF DESCRIPTION OF THE DRAWINGS

Features and advantages of embodiments of the present invention will become apparent as the following detailed description proceeds, and upon reference to the drawings, wherein like numerals depict like parts, and in which:

FIG. 1 shows a block diagram illustrating a control circuit, in accordance with embodiments of the present invention;

FIG. 2 shows a diagram illustrating a control signal and an indicating signal, in accordance with embodiments of the present invention;

FIG. 3 shows a block diagram illustrating a controller, in accordance with embodiments of the present invention;

FIG. 4 shows a block diagram illustrating a logic circuit, in accordance with embodiments of the present invention;

FIG. 5 shows a flowchart of a method for controlling an intelligent device with a control circuit, in accordance with embodiments of the present invention;

FIG. 6 shows a flowchart of a method for controlling an intelligent device with a control circuit, in accordance with embodiments of the present invention;

FIG. 7 shows a flowchart of a method for controlling an intelligent device with a control circuit, in accordance with embodiments of the present invention;

FIG. 8 shows a block diagram illustrating a control circuit, in accordance with embodiments of the present invention; and

FIG. 9 shows a block diagram illustrating a control circuit, in accordance with embodiments of the present invention.

### DETAILED DESCRIPTION

Reference will now be made in detail to the embodiments of the present invention. While the invention will be described in combination with these embodiments, it will be understood that they are not intended to limit the invention to these embodiments. On the contrary, the invention is intended to cover alternatives, modifications and equivalents, which may be included within the spirit and scope of the invention as defined by the appended claims.

Furthermore, in the following detailed description of the present invention, numerous specific details are set forth in order to provide a thorough understanding of the present invention. However, it will be recognized by one of ordinary skill in the art that the present invention may be practiced without these specific details. In other instances, well known methods, procedures, components, and circuits have not been described in detail as not to unnecessarily obscure aspects of the present invention.

Some portions of the detailed descriptions that follow are presented in terms of procedures, logic blocks, processing, and other symbolic representations of operations on data bits within a computer memory. These descriptions and representations are the means used by those skilled in the data processing arts to most effectively convey the substance of their work to others skilled in the art. In the present application, a procedure, logic block, process, or the like, is conceived to be a self-consistent sequence of steps or instructions leading to a desired result. The steps are those utilizing physical manipulations of physical quantities. Usually, although not necessarily, these quantities take the form of electrical or magnetic signals capable of being stored, transferred, combined, compared, and otherwise manipulated in a computing system. It has proven convenient at times, principally for reasons of common usage, to refer to these signals as transactions, bits, values, elements, symbols, characters, samples, pixels, or the like.

It should be borne in mind, however, that all of these and similar terms are to be associated with the appropriate physical quantities and are merely convenient labels applied to these quantities. Unless specifically stated otherwise as apparent from the following discussions, it is appreciated that throughout the present disclosure, discussions utilizing terms such as “generating,” “recording,” “reading,” “receiving,” “receiving,” “measuring,” “controlling,” or the like, refer to actions and processes of a computing system or similar electronic computing device or processor. A computing system or similar electronic computing device manipulates and transforms data represented as physical (electronic) quantities within the computing system memories, registers or other such information storage, transmission or display devices.

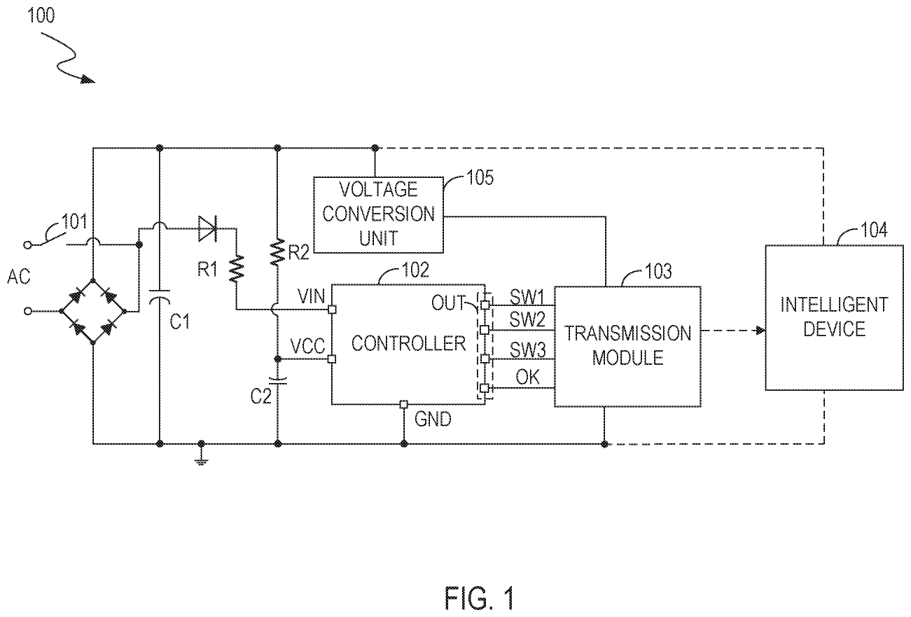

FIG. 1 shows a block diagram illustrating a control circuit 100, in accordance with an embodiment of the present invention. In the embodiment of FIG. 1, the control circuit 100 includes a power switch 101, a controller 102, and a transmission module 103. The power switch 101 is coupled to a power source AC. The power switch 101 is operable for turning on or turning off the power source AC. The power switch 101 can be, for example, a wall switch or a switch on an intelligent device 104.

The controller 102 includes an input terminal VIN, a power terminal VCC, and an output terminal OUT. The input terminal VIN is coupled to the power switch 101, and generates a parameter signal indicating an on/off state of the power switch 101 according to the on/off state of the power switch 101. For example, when the power switch 101 is turned on, the amount of voltage (voltage value) at the input terminal VIN exceeds a preset voltage value, or the amount of current (current value) flowing through the input terminal VIN exceeds a preset current value. The parameter signal is the voltage value at the input terminal VIN or the current value flowing through the input terminal VIN. The preset voltage value and the preset current value can be specified by design and/or set by a user.

The power terminal VCC is coupled to the power source AC, receives electric power supplied by the power source AC, and supplies electric power to the controller 102. The output terminal OUT is coupled to the transmission module 103, and outputs an indicating signal and a control signal, to enable the transmission module 103 to read the control signal according to the indicating signal, thus selecting the operating mode of the intelligent device 104. As will be described, there can be multiple operating modes, and the control signal is used to select an operating mode.

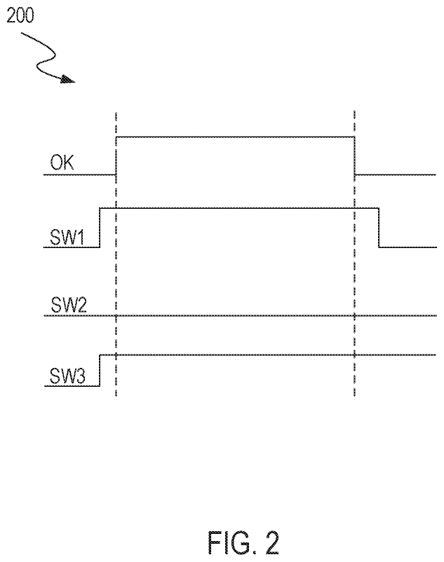

In an embodiment, the output terminal OUT includes control terminals SW1, SW2, and SW3, and an indicating terminal OK. The control terminals SW1, SW2, and SW3 transmit the control signal generated by the controller 102. For example, if the control signal is “101”, then the control terminal SW1 transmits the first value “1” of the control signal, the control terminal SW2 transmits the second value “0” of the control signal, and the control terminal SW3 transmits the third value “1” of the control signal. The indicating terminal OK transmits the indicating signal generated by the controller 102, to enable the transmission module 103 to read the control signal according to the indicating signal. Continuing with the above example, and referring to FIG. 2, when the indicating signal is in a first state (e.g., a high level), the transmission module 103 reads “1” of the control signal through the control terminal SW1, reads “0” of the control signal through the control terminal SW2, and reads “1” of the control signal through the control terminal SW3. When the indicating signal is in a second state (e.g., a low level), the transmission module 103 does not read the control signal through the control terminals SW1, SW2, and SW3.

The transmission module 103 reads and transmits the control signal according to the indicating signal, to select the operating mode of the intelligent device 104. For example, when the indicating signal is in a first state (e.g., a high level), the transmission module 103 reads the control signal. When the indicating signal is in a second state (e.g., a low level), the transmission module 103 does not read the control signal. The transmission module 103 includes, but is not limited to, a Bluetooth module, a WiFi module, or an infrared module. In addition, the transmission module 103 directly receives the control signal transmitted by a mobile terminal or a remote control, and transmits the control signal to the intelligent device 104 to select the operating mode of the intelligent device 104.

In the FIG. 1 embodiment, the control circuit 100 includes a voltage conversion unit 105. The voltage conversion unit 105 is coupled between the power source AC and the transmission module 103. The voltage conversion unit 105 converts a voltage supplied by the power source AC to a voltage required by the transmission module 103. In an embodiment, the voltage conversion unit 105 converts 220 V alternating current supplied by the power source AC to 3.3 V direct current, to power the transmission module 103.

In the FIG. 1 embodiment, the control circuit 100 includes the intelligent device 104. The intelligent device 104 receives the control signal and operates in an operating mode that is selected according to the control signal. The intelligent device 104 can be connected to the control circuit 100 in a wired manner (e.g., using a physical wire). That is, the intelligent device 104 and the control circuit 100 can be used together, as a connected component. Alternatively, the intelligent device 104 can be wirelessly coupled to the control circuit 100. That is, the intelligent device 104 can be used as an independent component, separated from the control circuit 100. Generally speaking, the intelligent device 104 is communicatively coupled to the control circuit 100. The intelligent device 104 includes, but is not limited to, intelligent LED (Light Emitting Diode) light sources, intelligent fans, and intelligent toasters.

In an embodiment, the intelligent device 104 is or includes intelligent LED light sources. The intelligent LED light sources can be placed in different operating modes by controlling the number of times the power switch 101 is turned on or off, the length of a turned-on time period of the power switch 101, and the length of a turned-off time period of the power switch 101. In different operating modes, the brightness levels and/or the color temperatures of the intelligent LED light sources are also different. For example, the operating modes of the intelligent LED light sources include mode A, mode B, and mode C, where mode A is a default mode. When the power switch 101 is turned on for the first time, the intelligent LED light sources operate in mode A. When the power switch 101 is turned off (for the first time) and turned on again (for the second time) within a preset time period, the intelligent LED light sources operate in mode B. Further, when the power switch 101 is turned off (for the second time) and turned on again (for the third time) within the preset time period, the intelligent LED light sources operate in mode C. For example, the LED light sources may be at their highest brightness level in mode A, their lowest brightness level in mode C, and an intermediate brightness level in mode B. Similarly, in other embodiments in which the intelligent device 104 is or includes intelligent fans or intelligent toasters, the rotating speed and the operating time of the intelligent fans are different, and the baking temperature and the baking time of the toasters are different.

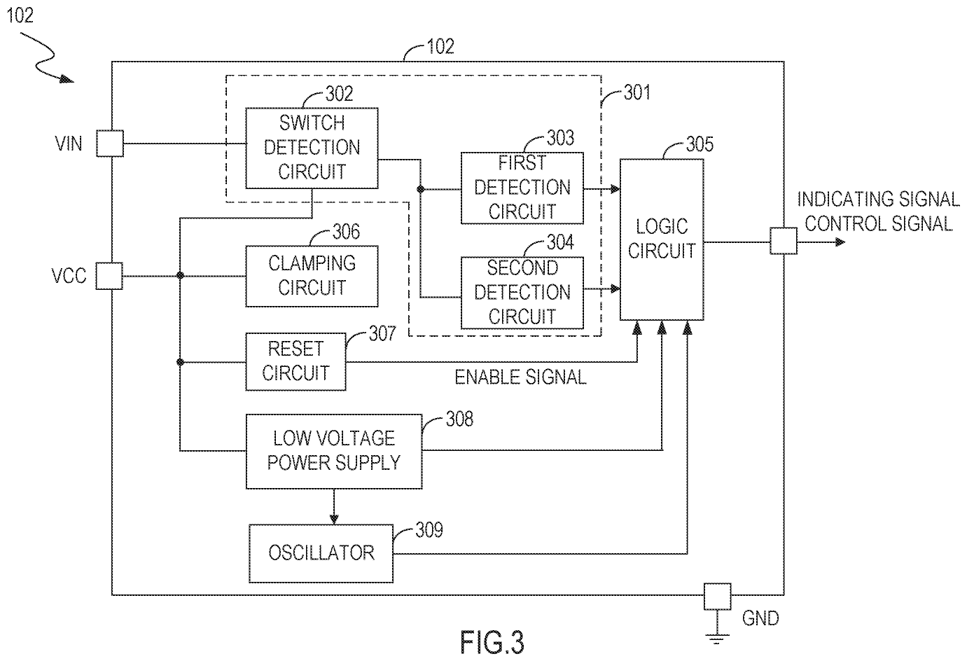

FIG. 3 shows a block diagram illustrating a controller 102, in accordance with embodiments of the present invention. FIG. 3 is described in conjunction with FIG. 1. The controller 102 includes a detection circuit 301. The detection circuit 301 is coupled to the input terminal VIN. The detection circuit 301 generates a voltage signal according to the aforementioned parameter signal (see discussion of FIG. 1) indicating the on/off state of the power switch 101, where the parameter signal is generated by the input terminal VIN. In an embodiment, the detection circuit 301 includes a switch detection circuit 302, a first detection circuit 303, and a second detection circuit 304.

The switch detection circuit 302 is coupled to the input terminal VIN. The switch detection circuit 302 generates a switch signal indicating the on/off state of the power switch 101 according to the parameter signal. For example, when the switch detection circuit 302 determines that the amount of current (the current value) flowing through the input terminal VIN exceeds the preset current value, or that the amount of voltage (the voltage value) at the input terminal VIN exceeds the preset voltage value, then the switch detection circuit 302 generates the switch signal indicating that the power switch 101 is turned on. When the switch detection circuit 302 determines that the current value flowing through the input terminal VIN does not exceed the preset current value, or that the voltage value at the input terminal VIN does not exceed the preset voltage value, then the switch detection circuit 302 generates the switch signal indicating that the power switch 101 is turned off. That is, the switch detection circuit 302 generates the switch signal indicating the on/off state of the power switch 101 by determining the current value flowing through the input terminal VIN or by determining the voltage value at the input terminal VIN.

The first detection circuit 303 is coupled to the switch detection circuit 302. When the switch signal indicates that the power switch 101 is turned on, the first detection circuit 303 generates a first voltage signal indicating that the power switch 101 is turned on. Specifically, when the power switch 101 is turned on, the switch detection circuit 302 generates the switch signal indicating that the power switch 101 is turned on. The first detection circuit 303 receives the switch signal and generates the first voltage signal (e.g., a high level signal) indicating that the power switch 101 is turned on. Otherwise, the first voltage signal generated by the first detection circuit 303 is a low level signal (indicating that the power switch 101 is turned off).

The second detection circuit 304 is coupled to the switch detection circuit 302. When the switch signal indicates that the power switch 101 is turned off, the second detection circuit 304 generates a second voltage signal indicating that the power switch 101 is turned off. Specifically, when the power switch 101 is turned off, the switch detection circuit 302 generates the switch signal indicating that the power switch 101 is turned off. The second detection circuit 304 receives the switch signal and generates the second voltage signal (e.g., a high level signal) indicating that the power switch 101 is turned off. Otherwise, the second voltage signal generated by the second detection circuit 304 is a low level signal (indicating that the power switch 101 is turned on).

In the FIG. 3 embodiment, the controller 102 further includes a logic circuit 305. The logic circuit 305 is coupled to the detection circuit 301. The logic circuit 305 generates the aforementioned control signal and indicating signal (see discussion of FIG. 1) according to the voltage signal (e.g., the first voltage signal and the second voltage signal), to enable the transmission module 103 to read the control signal according to the indicating signal. Specifically, the logic circuit 305 is coupled to the first detection circuit 303 and the second detection circuit 304. The logic circuit 305 receives the first voltage signal and the second voltage signal. If both the first voltage signal and the second voltage signal are at the high level, then the logic circuit 305 generates the control signal and the indicating signal, to enable the transmission module 103 to read the control signal according to the indicating signal, thus selecting the operating mode of the intelligent device 104. If either the first voltage signal or the second voltage signal is at the low level, then the logic circuit 305 does not generate the control signal and the indicating signal. In an embodiment, the logic circuit 305 includes a timing module 401 and a counting module 405 (the timing module 401 and the counting module 405 are described below).

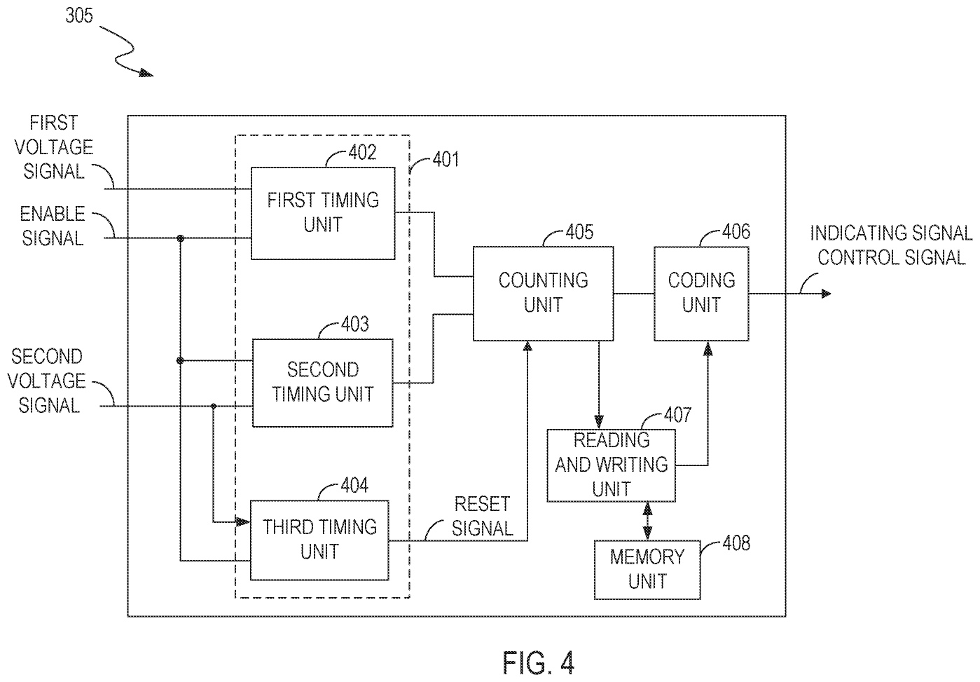

The controller 102 further includes a reset circuit 307. The reset circuit 307 is coupled between the power terminal VCC and the logic circuit 305. The reset circuit 307 generates an enable signal to enable the logic circuit 305 according to a monitoring voltage at the power terminal VCC. Specifically, the reset circuit 307 is coupled to a first timing unit 402, a second timing unit 403, and a third timing unit 404 (described in FIG. 4 below). When the monitoring voltage at the power terminal VCC is greater than a start-up voltage (e.g., 15 V) for the first time, the reset circuit 307 generates the enable signal. The first timing unit 402, the second timing unit 403, and the third timing unit 404 are started according to the enable signal generated by the reset circuit 307.

In an embodiment, when the power switch 101 is turned on, the monitoring voltage is pulled up from 0 V. When the monitoring voltage is greater than the start-up voltage (15 V) for the first time, the reset circuit 307 transmits the enable signal. The first timing unit 402, the second timing unit 403, and the third timing unit 404 are started according to the enable signal generated by the reset circuit 307. When the power switch 101 is turned off, the monitoring voltage begins to drop. When the monitoring voltage is lower than a turned-off voltage (e.g., 10 V), the times recorded by the first timing unit 402 and the second timing unit 403 are cleared. When the monitoring voltage is lower than a shutdown voltage (e.g., 4 V), a count value recorded by the counting unit 405 is cleared.

In addition, when the power switch 101 is turned on again within a preset reset time period T_{SET} after being turned off, or when the monitoring voltage is not lower than the shutdown voltage (e.g., 4 V), the third timing unit 404 does not transmit the reset signal, and the count value recorded by the counting unit 405 cannot be reset to the default value. When the power switch 101 is not turned on within the preset reset time period T_{SET} after being turned off, the third timing unit 404 transmits the reset signal, and the count value recorded by the counting unit 405 is reset to the default value; or, when the monitoring voltage is lower than the shutdown voltage (e.g., 4 V) before the power switch 101 is turned on, the count value recorded by the counting unit 405 is reset to the default value.

In the FIG. 3 embodiment, the controller 102 further includes a clamping circuit 306. The clamping circuit 306 is coupled to the power terminal VCC. The clamping circuit 306 clamps the monitoring voltage at the power terminal VCC to a preset voltage value (e.g., 24 V) to protect the controller 102.

In the FIG. 3 embodiment, the controller 102 includes a low voltage power supply 308. The low voltage power supply 308 is coupled between the power terminal VCC and the logic circuit 305. The low voltage power supply 308 supplies electric power to the logic circuit 305.

In the FIG. 3 embodiment, the controller 102 further includes an oscillator 309. The oscillator 309 is coupled between the power terminal VCC and the logic circuit 305. The oscillator 309 generates a clock signal to enable the components in the controller 102 to operate in a coordinated and orderly manner according to the clock signal. The electric power required by the oscillator 309 is supplied by the low voltage power supply 308.

FIG. 4 shows a block diagram illustrating a logic circuit 305, in accordance with embodiments of the present invention. FIG. 4 is described in conjunction with FIG. 3. The logic circuit 305 includes a timing module 401 and a counting unit 405. The timing module 401 is coupled to the detection circuit 301. When the power switch 101 is turned on again after previously being turned off, the timing module 401 measures and records a turned-off time period T_{OFF} (the amount of time that the power switch 101 was turned off) or a turned-on time period T_{ON} (the amount of time that the power switch 101 was turned on), according to the voltage signal (the first voltage signal and the second voltage signal) output by the detection circuit 301. Specifically, the timing module 401 is coupled to the first detection circuit 303 and the second detection circuit 304. When the power switch 101 is turned on again after being turned off, if the second voltage signal is at a high level (indicating that the power switch 101 is turned off), then the timing module 401 records the turned-off time period T_{OFF} when the power switch 101 is in the turned-off state. When the power switch 101 is turned on again after being turned off, if the first voltage signal is at a high level (indicating that the power switch 101 is turned on), then the timing module 401 records the turned-on time period T_{ON} when the power switch 101 is in the turned-on state. Otherwise, the timing module 401 does not record the turned-on time period T_{ON} or the turned-off time period T_{OFF}.

In an embodiment, the timing module 401 includes a first timing unit 402 and a second timing unit 403. The first timing unit 402 is coupled to the first detection circuit 303. The first timing unit 402 records the turned-on time period T_{ON} of the power switch 101 according to the first voltage signal, and generates a first counting signal according to the turned-on time period T_{ON}. Specifically, if the first voltage signal is at a high level, then the first timing unit 402 records the turned-on time period T_{ON} when the power switch 101 is in the turned-on state. When the length of the turned-on time period T_{ON} is greater than that of a first preset time period T_{SET1}, the first timing unit 402 generates a first counting signal (e.g., a high level signal) indicating a count. Otherwise, the first timing unit 402 generates a first counting signal (e.g., a low level signal) that does not indicate a count. When the first voltage signal is at a low level (indicating that the power switch 101 is turned off), the first timing unit 402 does not record the turned-on time period T_{ON}. The first preset time period T_{SET1} can be specified by design and/or set by a user. In the embodiment, the first preset time period T_{SET1} is 50 ms (milliseconds).

The second timing unit 403 is coupled to the second detection circuit 304. The second timing unit 403 records a first turned-off time period T_{OFF1} according to the second voltage signal, and generates a second counting signal according to the first turned-off time period T_{OFF1}. Specifically, if the second voltage signal is at a high level, then the second timing unit 403 records the first turned-off time period T_{OFF1} when the power switch 101 is in the turned-off state. When the length of the first turned-off time period T_{OFF1} is greater than that of a second preset time period T_{SET2}, the second timing unit 403 generates a second counting signal (e.g., a high level signal) indicating a count. Otherwise, the second timing unit 403 generates a second counting signal (e.g., a low level signal) that does not indicate a count. When the second voltage signal is at a low level (indicating that the power switch 101 is turned on), the second timing unit 403 does not record the turned-off time period. The second preset time period T_{SET2} can be specified by design and/or set by a user. In the embodiment, the second preset time period T_{SET2} is 50 ms.

In an embodiment, the timing module 401 includes a third timing unit 404. The third timing unit 404 is coupled between the second detection circuit 304 and the counting unit 405. The third timing unit 404 records a second turned-off time period T_{OFF2} according to the second voltage signal, and generates a reset signal according to the second turned-off time period T_{OFF2} to clear the count value recorded by the counting unit 405. Specifically, if the second voltage signal is at a high level, then the third timing unit 404 records the second turned-off time period T_{OFF2} when the power switch 101 is in the turned-off state. When the second turned-off time period T_{OFF2} is greater than the reset time period T_{SET}, the third timing unit 404 generates the reset signal to clear the count value recorded by the counting unit 405. When the second voltage signal is at a low level (indicating the power switch 101 is turned on), the third timing unit 404 does not record the turned-off time period. In the embodiment, the reset time period T_{SET} is three seconds.

The counting unit 405 is coupled to the timing module 401. The counting unit 405 updates the count value according to the counting signal, acquires an updated count value, and generates the indicating signal, to select the operating mode of the intelligent device 104. The updated count value is the aforementioned control signal.

Specifically, the counting unit 405 is coupled to the first timing unit 402, the second timing unit 403, and the third timing unit 404. The counting unit 405 receives the first counting signal output by the first timing unit 402, and also receives the second counting signal output by the second timing unit 403. When the first and second counting signals indicate a count (e.g., the first and second counting signals are both at a high level), the count value recorded by the counting unit 405 increases by one, and the counting unit 405 generates and transmits the indicating signal, to enable the transmission module 103 to read the count value according to the indicating signal. In other words, when the first and second counting signals indicate a count (e.g., the first and second counting signals are both at a high level), the actions of turning-on and turning-off the power switch 101 by a user are each regarded as an effective control action. In an embodiment, the counting unit 405 is a counter. The third timing unit 404 is described in detail above.

In an embodiment, the logic circuit 305 includes a coding unit 406. The coding unit 406 is coupled to the counting unit 405. The coding unit 406 encodes the count value recorded by the counting unit 405 and transmits the coded count value to the transmission module 103 through serial or parallel communications, to select the operating mode of the intelligent device 104.

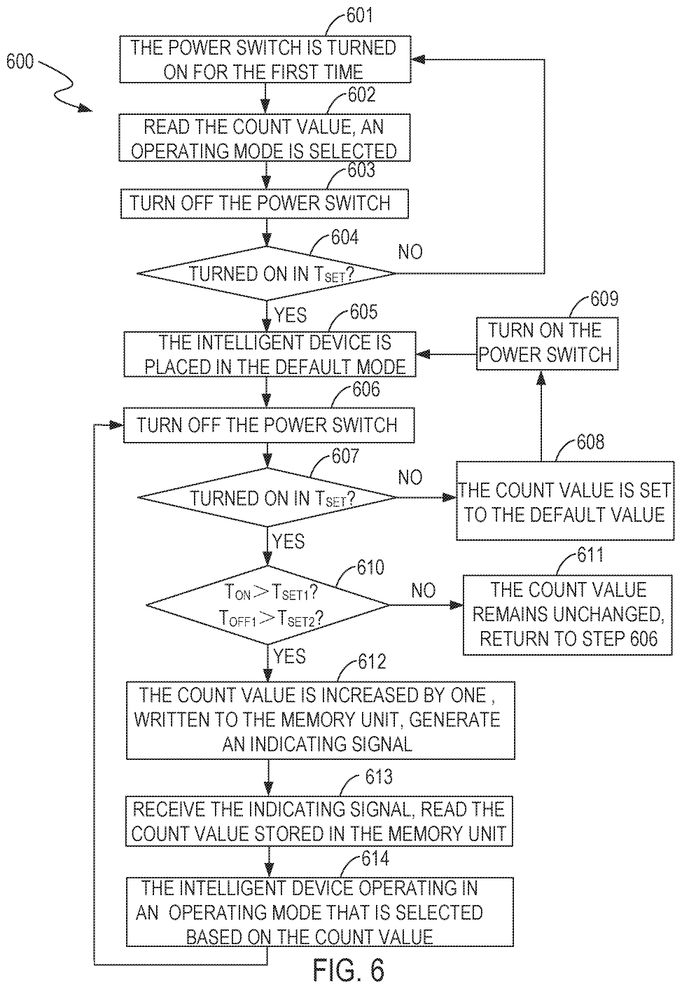

In an embodiment, the logic circuit 305 includes a reading and writing unit 407 and a memory unit 408. The reading and writing unit 407 is coupled between the counting unit 405 and the coding unit 406. When the monitoring voltage is increased to a reading and writing voltage (e.g., 24 V), the reading and writing unit 407 can perform a write operation or a read operation on the memory unit 408. The memory unit 408 stores the count value recorded by the counting unit 405. The count value is written to the memory unit 408 by the reading and writing unit 407, so that the last (previous) operating mode of the intelligent device 104 is remembered. When the power switch 101 is turned on again, the operating mode of the intelligent device 104 is still the last operating mode. The reading and writing unit 407 and the memory unit 408 are described in below in the discussion of FIG. 6.

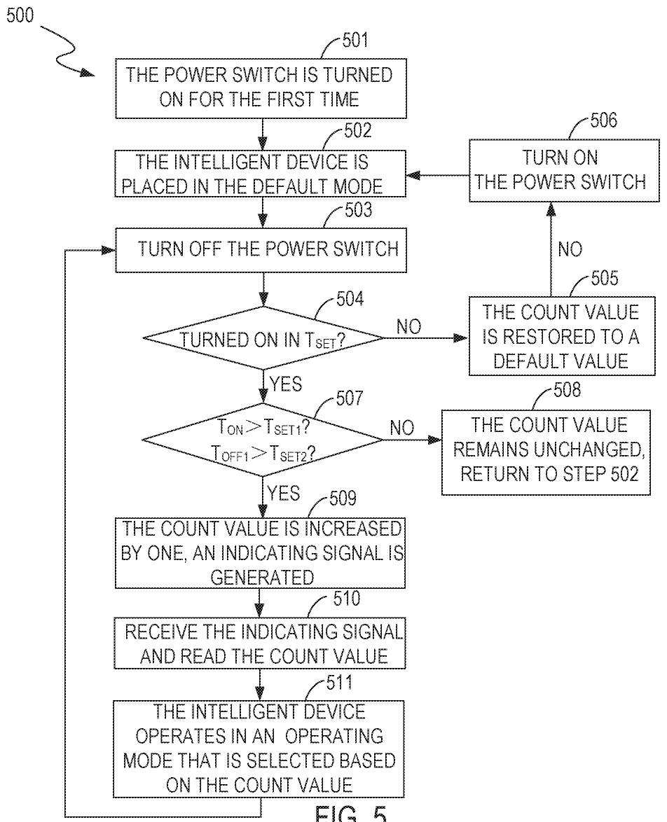

FIG. 5 shows a flowchart of a method 500 for controlling the intelligent device 104 with the control circuit 100, in accordance with embodiments of the present invention. FIG. 5 is described in conjunction with FIG. 1, FIG. 3, and FIG. 4. The method 500 utilizes the logic circuit 305 that does not include the reading and writing unit 407 and the memory unit 408.

In step 501, the power switch 101 is turned on for the first time.

In step 502, the intelligent device 104 is placed in the default mode.

In step 503, when the power switch 101 is turned off, a second timing unit 403 measures and records the first turned-off time period T_{OFF1}, and a third timing unit 404 measures and records the second turned-off time period T_{OFF2}.

In step 504, the logic circuit 305 determines whether the power switch 101 is turned on again within the reset time period T_{SET} after being turned off. That is, the logic circuit 305 determines whether the length of the second turned-off time period T_{OFF2} is less than that of the reset time period T_{SET}. If yes, step 504 is followed by step 507. Otherwise, step 504 is followed by step 505.

In step 505, the count value recorded by the counting unit 405 is restored to a default value.

In step 506, when the power switch 101 is turned on again, step 506 is followed by step 502.

In step 507, the logic circuit 305 determines whether the length of the turned-on time period T_{ON} recorded by the first timing unit 402 is greater than that of the first preset time period T_{SET1}, and whether the length of the first turned-off time period T_{OFF1} is greater than that of the second preset time period T_{SET2}. When both conditions are satisfied, step 507 is followed by step 509. Otherwise, step 507 is followed by step 508.

In step 508, the count value recorded by the counting unit 405 remains unchanged. That is, the power switch 101 is turned on again after being turned off, which is regarded as an invalid control action. Step 508 is followed by step 502.

In step 509, the count value recorded by the counting unit 405 is increased by one, and the counting unit 405 generates an indicating signal.

In step 510, the transmission module 103 receives the indicating signal, and reads the count value recorded by the counting unit 405 according to the indicating signal.

In step 511, the intelligent device 104 operates in an operating mode that is selected according to the count value. For example, if the count value is “000”, the intelligent device 104 operates in operating mode A; if the count value is “001”, the intelligent device 104 operates in operating mode B; if the count value is “011”, the intelligent device 104 operates in operating mode C; and so on. Subsequently, step 511 is followed by step 503, to continue to set the operating mode of the intelligent device 104 according to the on/off state of the power switch 101.

FIG. 6 shows a flowchart of a method 600 for controlling the intelligent device 104 with the control circuit 100, in accordance with embodiments of the present invention. FIG. 6 is described in conjunction with FIG. 1, FIG. 3, and FIG. 4. The method 600 utilizes the logic circuit 305 that includes the reading and writing unit 407 and the memory unit 408.

In step 601, the power switch 101 is turned on for the first time.

In step 602, the reading and writing unit 407 reads the count value stored in the memory unit 408. The intelligent device 104 operates in an operating mode that is selected according to the count value.

In step 603, when the power switch 101 is turned off, the second timing unit 403 measures and records the first turned-off time period T_{OFF1}, and the third timing unit 404 measures and records the second turned-off time period T_{OFF2}.

In step 604, the logic circuit 305 determines whether the power switch 101 is turned on again within the reset time period T_{SET} after being turned off. That is, the logic circuit 305 determines whether the length of the second turned-off time period T_{OFF2} is less than that of the reset time period T_{SET}. If yes, step 604 is followed by step 605. Otherwise, step 604 is followed by step 601.

In step 605, the power switch 101 is turned on again within the reset time period T_{SET} after being turned off, the controller 102 is reset, and the intelligent device 104 is placed in the default mode.

In step 606, when the power switch 101 is turned off, the second timing unit 403 measures and records the first turned-off time period T_{OFF1}, and the third timing unit 404 measures and records the second turned-off time period T_{OFF2}.

In step 607, the logic circuit 305 determines whether the power switch 101 is turned on again within the reset time period T_{SET} after being turned off. That is, the logic circuit 305 determines whether the length of the second turned-off time period T_{OFF2} is less than that of the reset time period T_{SET}. If yes, step 607 is followed by step 610. Otherwise, step 607 is followed by step 608.

In step 608, the count value recorded by the counting unit 405 is set to the default value.

In step 609, the power switch 101 is turned on. Step 609 is followed by step 605.

In step 610, the logic circuit 305 determines whether the length of the turned-on time period T_{ON} recorded by the first timing unit 402 is greater than that of a first preset time period T_{SET1}, and whether the length of the first turned-off time period T_{OFF1} is greater than that of a second preset time period T_{SET2}. When both conditions are satisfied, step 610 is followed by step 612. Otherwise, step 610 is followed by step 611.

In step 611, the count value recorded by the counting unit 405 remains unchanged. That is, the power switch 101 is turned on again after being turned off, but that action is considered to be an invalid control action. Step 611 is followed by step 606.

In step 612, the count value recorded by the counting unit 405 is increased by one and the increased count value is written to the memory unit 408. Also, the counting unit 405 generates an indicating signal.

In step 613, the transmission module 103 receives the indicating signal, and reads the count value stored in the memory unit 408 through the reading and writing unit 407 according to the indicating signal.

In step 614, the intelligent device 104 operates in an operating mode that is selected according to the count value. Subsequently, step 614 is followed by step 606, to continue to set the operating mode of the intelligent device 104 according to the on/off state of the power switch 101.

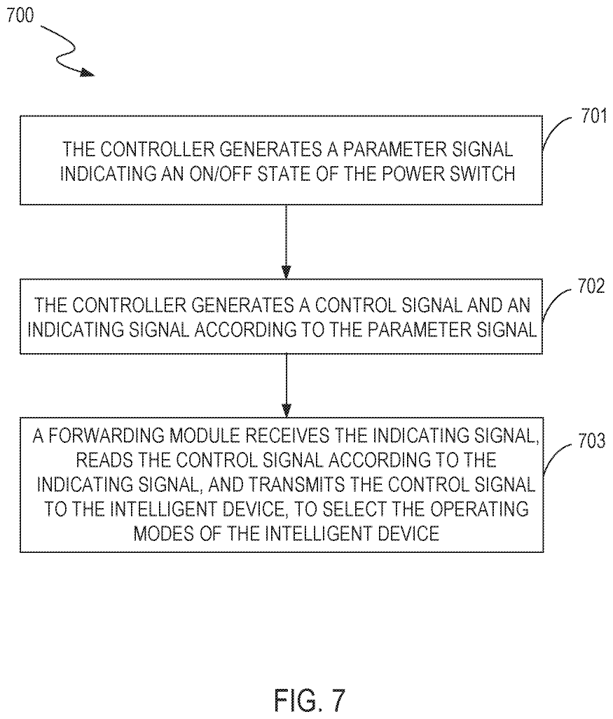

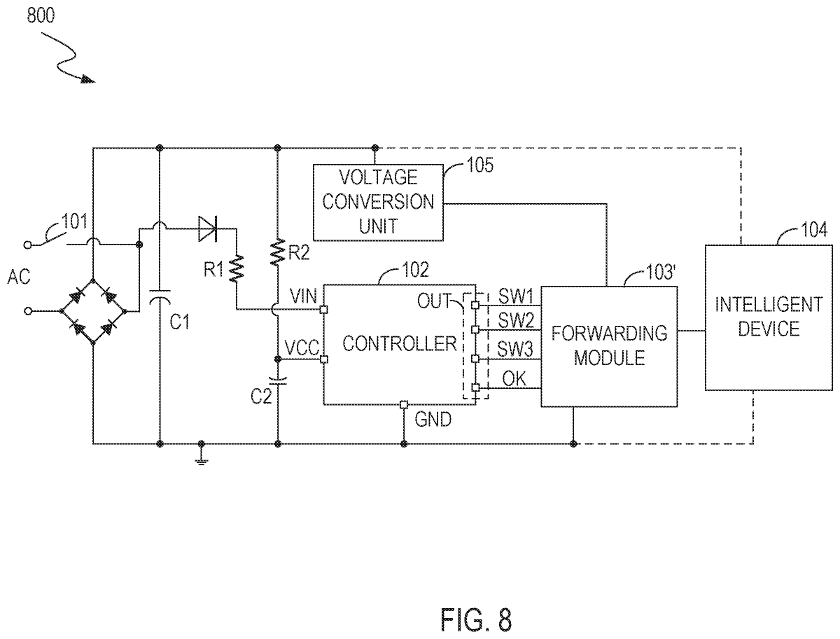

FIG. 7 shows a flowchart of a method 700 for controlling the intelligent device 104 with the control circuit 100, in accordance with embodiments of the present invention. FIG. 7 is described in conjunction with FIG. 1 and FIG. 8 (FIG. 8 is described below).

In step 701, the controller 102 generates a parameter signal indicating an on/off state of the power switch 101.

In step 702, the controller 102 generates a control signal and an indicating signal according to the parameter signal.

In step 703, a forwarding module 103′ (FIG. 8) receives the indicating signal, reads the control signal according to the indicating signal, and transmits the control signal to the intelligent device 104, to select the operating mode of the intelligent device 104.

FIG. 8 shows a block diagram illustrating a control circuit 800, in accordance with embodiments of the present invention. Elements labeled the same as in FIG. 1 have similar functions. FIG. 8 is described in conjunction with FIG. 1. The difference between the embodiments of FIG. 8 and FIG. 1 is that a forwarding module 103′ replaces the transmission module 103 in FIG. 1. The forwarding module 103′ is coupled to the intelligent device 104 in a wired manner, or the forwarding module 103′ is wirelessly coupled to the intelligent device 104. The forwarding module 103′ selects the operating mode of the intelligent device 104 according to a control signal and an indicating signal output by the controller 102. In an embodiment, the forwarding module 103′ includes a microcontroller unit (MCU). The microcontroller unit is connected to the intelligent device 104 in a wired manner. The microcontroller unit selects the operating mode of the intelligent device 104 according to the indicating signal and the control signal output by the controller 102. In the example of FIG. 8, the forwarding module 103′ is located outside of the intelligent device 104, in other embodiments, the forwarding module 103′ is integrated within the intelligent device 104.

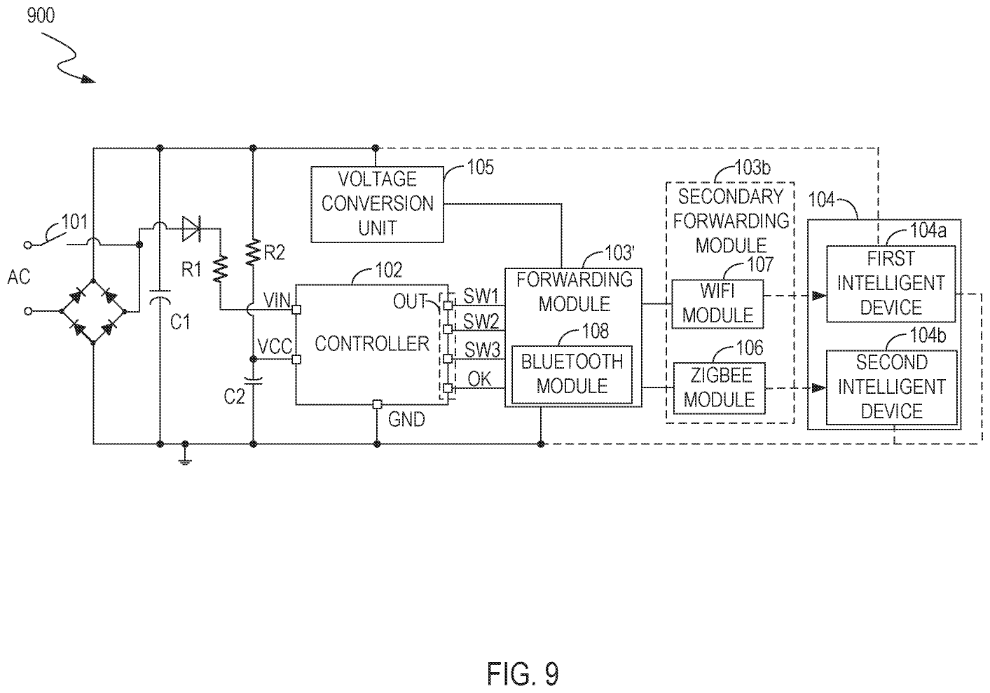

FIG. 9 shows a block diagram illustrating a control circuit 900, in accordance with embodiments of the present invention. Elements labeled the same as in FIG. 1 have similar functions. FIG. 9 is described in conjunction with FIG. 1 and FIG. 8. In the example of FIG. 9, the control circuit 900 includes a secondary forwarding module 103b coupled between the forwarding module 103′ and the intelligent device 104 (which includes a first intelligent device 104a and a second intelligent device 104b). The forwarding module 103′ is coupled to the secondary forwarding module 103b in a wired manner, or the forwarding module 103′ is wirelessly coupled to the secondary forwarding module 103b. The secondary forwarding module 103b is coupled to the intelligent device 104 in a wired manner, or the secondary forwarding module 103b is wirelessly coupled to the intelligent device 104. The forwarding module 103′ reads a control signal according to an indicating signal, generates a signal, and transmits the signal to the secondary forwarding module 103b. The signal can be the control signal read from the controller 102 by the forwarding module 103′, or it can be acquired by processing the control signal with the forwarding module 103′ (for example, in order to meet the requirements of different transmission protocols, as described below). The secondary forwarding module 103b selects the operating mode of the intelligent device 104 according to the signal.

In an embodiment, the forwarding module 103′ includes a Bluetooth module 108, and the secondary forwarding module 103b includes a WiFi module 107 and/or a ZigBee module 106. The forwarding module 103′ is connected to the secondary forwarding module 103b in a wired manner (e.g., via a cable connection between the forwarding module 103′ and the secondary forwarding module 103b through terminals GPIO, terminals GPIO not shown in the figures). The secondary forwarding module 103b is wirelessly coupled to the intelligent device 104. The WiFi module 107 controls (selects) the operating mode of the first intelligent device 104a according to the signal from the Bluetooth module 108. The ZigBee module 106 selects the operating mode of the second intelligent device 104b according to the signal from the Bluetooth module 108.

While the foregoing description and drawings represent embodiments of the present invention, it will be understood that various additions, modifications, and substitutions may be made therein without departing from the spirit and scope of the principles of the present invention as defined in the accompanying claims. One skilled in the art will appreciate that the invention may be used with many modifications of form, structure, arrangement, proportions, materials, elements, and components and otherwise, used in the practice of the invention, which are particularly adapted to specific environments and operative requirements without departing from the principles of the present invention. The presently disclosed embodiments are therefore to be considered in all respects as illustrative and not restrictive, the scope of the invention being indicated by the appended claims and their legal equivalents, and not limited to the foregoing description.

What is claimed is:

1. A controller, comprising:
an input terminal, coupled to a power switch, operable for generating a parameter signal indicating an on/off state of said power switch;
a power terminal, coupled to a power source, operable for receiving electric power supplied by said power source to power said controller;
an output terminal, coupled to a forwarding module, operable for outputting an indicating signal and a control signal, wherein said forwarding module reads said control signal based on said indicating signal, thus selecting an operating mode of an intelligent device communicatively coupled to said controller, wherein both said control signal and said indicating signal are generated by said controller based on said parameter signal.

2. The controller of claim 1, wherein if said parameter signal indicates said power switch is turned on again within a reset time period after being turned off, then said controller generates said control signal and said indicating signal.

3. The controller of claim 1, further comprising:
a detection circuit, coupled to said input terminal, operable for generating a voltage signal based on said parameter signal; and
a logic circuit, coupled to said detection circuit, operable for generating said control signal and said indicating signal based on said voltage signal.

4. The controller of claim 3, wherein said voltage signal comprises a first voltage signal and a second voltage signal, wherein said detection circuit comprises:
a switch detection circuit, coupled to said input terminal, operable for generating a switch signal indicating said on/off state of said power switch based on said parameter signal;
a first detection circuit, coupled to said switch detection circuit, operable for generating said first voltage signal indicating that said power switch is turned on based on said switch signal; and
a second detection circuit, coupled to said switch detection circuit, operable for generating said second voltage signal indicating that said power switch is turned off based on said switch signal.

5. The controller of claim 4, wherein said logic circuit comprises:
a timing module, coupled to said detection circuit, operable for measuring and recording a turned-off time period and a turned-on time period when said power switch is turned on again after being turned off, based on said first voltage signal and said second voltage signal, and for generating a counting signal based on said turned-off time period and said turned-on time period; and
a counting unit, coupled to said timing module, operable for updating a count value based on said counting signal, for acquiring an updated count value, and for generating said indicating signal, wherein said updated count value is said control signal.

6. The controller of claim 5, wherein said timing module comprises:
a first timing unit, coupled to said first detection circuit, operable for measuring and recording said turned-on time period based on said first voltage signal, and for generating a first counting signal based on said turned-on time period; and
a second timing unit, coupled to said second detection circuit, operable for measuring and recording a first turned-off time period based on said second voltage signal, and for generating a second counting signal based on said first turned-off time period.

7. The controller of claim 5, wherein said timing module further comprises:
a timing unit, coupled between said second detection circuit and said counting unit, operable for measuring and recording a second turned-off time period of said power switch based on said second voltage signal, and for generating a reset signal based on said second turned-off time period to clear the count value recorded by said counting unit.

8. The controller of claim 3, further comprising:
a reset circuit, coupled between said power terminal and said logic circuit, operable for generating an enable signal based on a monitoring voltage at said power terminal to enable said logic circuit.

9. The controller of claim 1, wherein said forwarding module is coupled to said intelligent device in a wired manner.

10. The controller of claim 1, wherein said forwarding module is wirelessly coupled to said intelligent device.

11. The controller of claim 10, wherein said forwarding module reads said control signal based on said indicating signal, and generates and transmits a signal to a secondary forwarding module; wherein said secondary forwarding module is coupled between said forwarding module and said intelligent device, and wherein said secondary forwarding module is operable for selecting said operating mode of said intelligent device based on said signal.

12. A control circuit, comprising:
a controller, coupled to a power switch, operable for receiving electric power from a power source, and for generating a control signal and an indicating signal based on an on/off state of said power switch; and
a forwarding module, coupled to said controller, operable for receiving said indicating signal, for reading said control signal based on said indicating signal, and for transmitting said control signal to an intelligent device, to select an operating mode of said intelligent device.

13. The control circuit of claim 12, wherein said controller generates a parameter signal based on said on/off state of said power switch, wherein when said parameter signal indicates said power switch is turned on again within a reset time period after being turned off, said controller generates said control signal and said indicating signal.

14. The control circuit of claim 13, wherein said controller comprises:
a detection circuit, coupled to said power switch, operable for generating a voltage signal based on said parameter signal; and
a logic circuit, coupled to said detection circuit, operable for generating said control signal and said indicating signal based on said voltage signal.

15. The control circuit of claim 14, wherein said voltage signal comprises a first voltage signal and a second voltage signal, wherein said detection circuit comprises:
a switch detection circuit, coupled to said power switch, operable for generating a switch signal indicating said on/off state of said power switch based on said parameter signal;
a first detection circuit, coupled to said switch detection circuit, operable for generating said first voltage signal indicating that said power switch is turned on based on said switch signal; and
a second detection circuit, coupled to said switch detection circuit, operable for generating said second voltage signal indicating that said power switch is turned off based on said switch signal.

16. The control circuit of claim 15, wherein said logic circuit comprises:
a timing module, coupled to said detection circuit, operable for measuring and recording a turned-off time period and a turned-on time period when said power switch is turned on again after being turned off, based on said first voltage signal and said second voltage signal, and for generating a counting signal based on said turned-off time period and said turned-on time period; and
a counting unit, coupled to said timing module, operable for updating a count value based on said counting signal, for acquiring an updated count value, and for generating said indicating signal; wherein said updated count value is said control signal.

17. The control circuit of claim 16, wherein said timing module comprises:
a first timing unit, coupled to said first detection circuit, operable for measuring and recording said turned-on time period based on said first voltage signal, and for generating a first counting signal based on said turned-on time; and
a second timing unit, coupled to said second detection circuit, operable for measuring and recording a first turned-off time period based on said second voltage signal, and for generating a second counting signal based on said first turned-off time period.

18. The control circuit of claim 16, wherein said timing module comprises:
a timing unit, coupled between said second detection circuit and said counting unit, operable for measuring and recording a second turned-off time period of said power switch based on said second voltage signal, and for generating a reset signal based on said second turned-off time period to clear the count value recorded by said counting unit.

19. The control circuit of claim 14, wherein said controller further comprises:
a reset circuit, coupled to said logic circuit, operable for generating an enable signal based on a monitoring voltage detected by said controller to enable said logic circuit.

20. The control circuit of claim 12, wherein said forwarding module is coupled to said intelligent device in a wired manner.

21. The control circuit of claim 12, wherein said forwarding module is wirelessly coupled to said intelligent device.

22. The control circuit of claim 21, further comprising:
a secondary forwarding module, coupled between said forwarding module and said intelligent device, wherein said forwarding module reads said control signal based on said indicating signal, and generates and transmits a signal to said secondary forwarding module; wherein said secondary forwarding module selects said operating mode of said intelligent device based on said signal.

23. A method for controlling an intelligent device with a control circuit, said control circuit comprising a controller coupled to a power switch and a forwarding module, wherein said controller is coupled to said forwarding module, said method comprising:
generating, using said controller, a parameter signal indicating an on/off state of said power switch;
generating, using said controller, a control signal and an indicating signal based on said parameter signal; and
receiving, using said forwarding module, said indicating signal, reading said control signal based on said indicating signal, and transmitting said control signal to said intelligent device, to select an operating mode of said intelligent device.

24. The method of claim 23, wherein said generating a control signal and an indicating signal based on said parameter signal comprises:
generating, using a detection circuit, a voltage signal when said parameter signal indicates that said power switch is turned on again after being turned off;
measuring and recording, using a timing module, a turned-off time period and a turned-on time period when said power switch is turned on again after being turned off based on said voltage signal, and generating a counting signal based on said turned-off time period and said turned-on time period; and
generating, using a counting unit, said control signal and said indicating signal based on said counting signal.

25. The method of claim 23, further comprising:
generating, using a timing unit, a reset signal to clear a count value recorded by a counting unit, when said parameter signal indicates said power switch is not turned on within a reset time period after being turned off.

26. The method of claim 23, further comprising:
generating, using a reset circuit, an enable signal to enable a logic circuit based on a monitoring voltage detected by said controller.

27. The method of claim 23, wherein said forwarding module is coupled to said intelligent device in a wired manner.

28. The method of claim 23, wherein said forwarding module is wirelessly coupled to said intelligent device.

29. The method of claim 28, further comprising:
reading, using said forwarding module, said control signal based on said indicating signal, and generating and transmitting a signal to a secondary forwarding module coupled between said forwarding module and said intelligent device; and
selecting, using said secondary forwarding module, an operating mode of said intelligent device based on said signal.
